(19) United States
(12) Patent Application Publication
(10) Pub. No.: US 2025/0029964 A1
(43) Pub. Date: Jan. 23, 2025

(54) DISPLAY PANEL AND METHOD OF FABRICATING DISPLAY PANEL

(71) Applicant: LG DISPLAY CO., LTD., Seoul (KR)

(72) Inventors: Jong Soo HAN, Paju-si (KR); Yong Hoon LEE, Paju-si (KR); Woo Sung KIM, Paju-si (KR); Hyoung Sun PARK, Paju-si (KR); Hyun Seok NA, Paju-si (KR); Hyun Chyol SHIN, Paju-si (KR); Seong Soo CHO, Paju-si (KR); Kyeong Min YUK, Paju-si (KR)

(73) Assignee: LG DISPLAY CO., LTD., Seoul (KR)

(21) Appl. No.: 18/775,625

(22) Filed: Jul. 17, 2024

(30) Foreign Application Priority Data
Jul. 20, 2023 (KR) 10-2023-0094593

(51) Int. Cl. H01L 25/075; H01L 33/44; H01L 33/58; H01L 33/62

(52) U.S. Cl. CPC H01L 25/0753; H01L 33/44; H01L 33/58; H01L 33/62; H01L 2933/0025; H01L 2933/0066; H01L 2933/0091

(57) ABSTRACT

A display device includes a bank pattern disposed on a substrate, a first electrode pattern disposed on the bank pattern, a light-emitting element disposed on the first electrode pattern to be electrically connected to the first electrode pattern, a second electrode pattern configured to cover the light-emitting element, an inorganic insulating layer configured to cover the bank pattern, the first electrode pattern, and the light-emitting element between the first electrode pattern and the second electrode pattern, and a diffusion layer which includes a plurality of diffusion particles and is in contact with the inorganic insulating layer.

### CROSS-REFERENCE TO RELATED APPLICATIONS

This application claims the priority of Korean Patent Application No. 10-2023-0094593, filed on Jul. 20, 2023, which is hereby incorporated by reference in its entirety.

### BACKGROUND

### Field of the Disclosure

The present disclosure relates to a display panel and a method of fabricating the display panel.

### Description of the Background

Electroluminescence display devices may be broadly dived into organic light-emitting display devices in which organic light-emitting diodes (OLEDs) are disposed in pixels and inorganic light-emitting display devices (hereinafter, referred to “LED display devices”) in which inorganic light-emitting diodes (hereinafter, referred to as “LEDs”) are disposed in pixels.

The electroluminescence display device displays images using self-luminous elements, and thus does not require a separate light source, for example, a backlight unit, and may be thin and implemented in various forms. The electroluminescence display device not only has excellent power consumption, an excellent response time, excellent luminance, a wide viewing angle, and the like but also has an excellent contrast ratio and color gamut as black gradations may be expressed as perfect black.

In an organic light-emitting display device, since an oxidation phenomenon between an organic light-emitting layer and an electrode may occur due to penetration of moisture and oxygen, a design for preventing the penetration of oxygen and moisture is required.

As an example of an inorganic light-emitting display device, a micro-LED display device in which micro-LEDs are disposed in pixels has been attracting attention as a next-generation display device. The micro-LED may be an inorganic LED with a size of 100 μm or less. Micro-LEDs are fabricated through a separate semiconductor process and transferred to pixel positions on a display panel substrate of the display device, and thus may be respectively disposed in sub-pixels for each color.

### SUMMARY

In a process of fabricating a display panel, since a gap is generated due to the weakening of adhesion between a passivation layer formed of AlOₓ and a diffusion layer (or sidewall diffuser SWD), a cathode may be affected by the expansion or contraction of the diffusion layer. Accordingly, disconnection may occur when the cathode is formed.

Accordingly, the present disclosure is directed to a display panel and a method of fabricating the display panel that substantially obviate one or more of problems due to limitations and disadvantages described above.

More specifically, the present disclosure is to provide a display device capable of improving the adhesion between a light-emitting element and a diffusion layer (SWD) to suppress cathode disconnection defects using an inorganic insulating layer having strong adhesion, and a method of fabricating the display device.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display panel includes a bank pattern disposed on a substrate, a first electrode pattern disposed on the bank pattern, a light-emitting element disposed on the first electrode pattern to be electrically connected to the first electrode pattern, a second electrode pattern configured to cover the light-emitting element, an inorganic insulating layer configured to cover the bank pattern, the first electrode pattern, and the light-emitting element between the first electrode pattern and the second electrode pattern, and a diffusion layer which includes a plurality of diffusion particles and is in contact with the inorganic insulating layer.

In another aspect of the present disclosure, a method for fabricating a display panel includes forming a bank pattern on a substrate, forming a first electrode pattern on the bank pattern, disposing a light-emitting element on the first electrode pattern to be electrically connected to the first electrode pattern, disposing an inorganic insulating layer configured to cover the bank pattern, the first electrode pattern, and the light-emitting element, disposing a diffusion layer which includes plurality of diffusion particles and is in contact with the inorganic insulating layer, planarizing the diffusion layer and the inorganic insulating layer to expose an upper portion of the light-emitting element, and disposing a second electrode pattern configured to cover the light-emitting element, the inorganic insulating layer, and the diffusion layer.

It is to be understood that both the foregoing general description and the following detailed description are exemplary and explanatory and are intended to provide further explanation of the disclosure as claimed.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a plan view illustrating one pixel in a display panel according to one aspect of the present disclosure;

FIG. 2 is a cross-sectional view illustrating a partial longitudinal cross-sectional structure of the display panel taken along line I-I′ in FIG. 1;

FIG. 3 is a cross-sectional view illustrating a partial longitudinal cross-sectional structure of the display panel taken along line II-II′ in FIG. 1;

FIG. 4 is a cross-sectional view illustrating a partial longitudinal cross-sectional structure of the display panel taken along line III-III′ in FIG. 1; and

FIGS. 5A to 5M are cross-sectional views of a process of fabricating the display panel according to one aspect of the present disclosure.

### DETAILED DESCRIPTION

Advantages and features of the present disclosure and a method of achieving the same should become clear with embodiments described in detail below with reference to the accompanying drawings. However, the present disclosure is not limited to the embodiments disclosed below and may be implemented with a variety of different forms. The present embodiments are merely provided to allow those skilled in the art to completely understand the scope of the present disclosure, and the present disclosure is defined only by the scope of the claims.

The figures, dimensions, ratios, angles, numbers, and the like disclosed in the drawings for describing the embodiments of the present disclosure are merely illustrative and are not limited to matters shown in the present disclosure. Further, in describing the present disclosure, detailed descriptions of well-known technologies will be omitted when it is determined that they may unnecessarily obscure the gist of the present disclosure.

Terms such as “including,” “having,” and “composed of” used herein are intended to allow other elements to be added unless the terms are used with the term “only.” When a component is expressed in the singular form, it may include a case in which the plural form is included unless otherwise explicitly stated.

Components are interpreted as including an ordinary error range even when not expressly stated.

For the description of a positional relationship, for example, when the positional relationship between two parts is described as “on,” “above,” “below,” “next to,” and the like, one or more parts may be interposed therebetween unless the term “immediately” or “directly” is used in the expression.

When an element or layer is disposed “on” another element or layer, the element is disposed directly on another element or layer or disposed on another element another layer with still another element therebetween.

In addition, the terms “first,” “second,” and the like may be used herein to describe various components, the components are not limited by the terms. These terms are used only to distinguish one component from another. Accordingly, a first component discussed below could be termed a second component without departing from the teachings of the present disclosure.

Like reference numerals generally denote like elements throughout the specification.

The size and thickness of each component illustrated in the drawings are shown for convenience of description, and the present disclosure is not necessarily limited to the size and thickness of the component illustrated.

The features of various embodiments of the present disclosure may be partially or entirely bonded to or combined with each other. The embodiments may be interoperated and performed in various ways technically and may be carried out independently of or in association with each other.

Hereinafter, various embodiments of the present disclosure will be described in detail with reference to the accompanying drawings.

A display device according to one aspect of the present disclosure includes a display region where an image is displayed or a display panel on which a screen is disposed, and a pixel driving circuit which drives pixels of the display panel. The display region includes a pixel region where the pixels are disposed. The pixel region includes a plurality of light-emitting regions. A light-emitting element is disposed in each of the light-emitting regions. The pixel driving circuit may be built into the display panel.

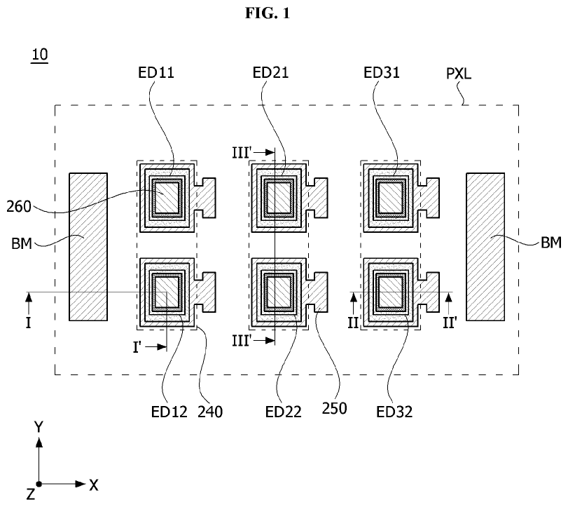

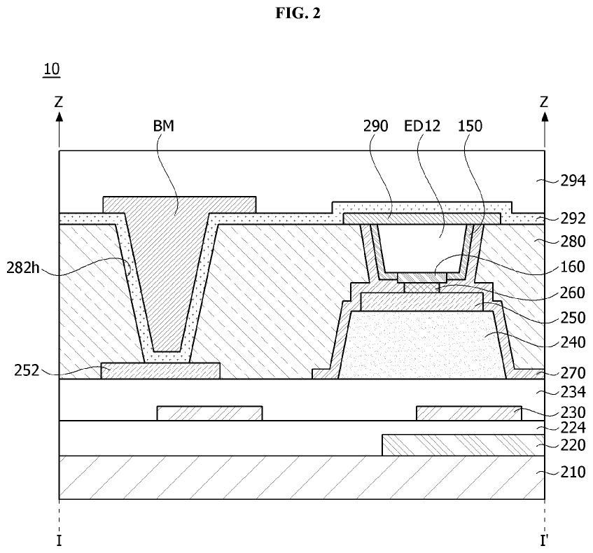

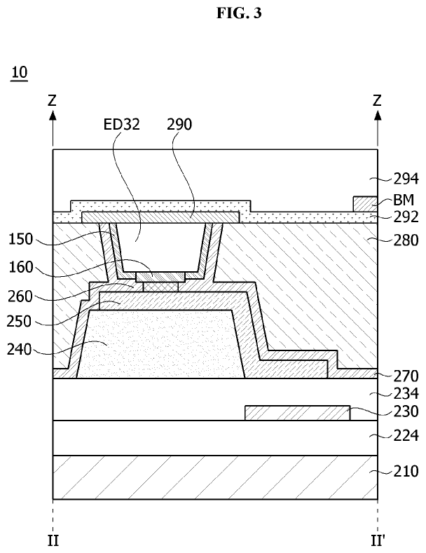

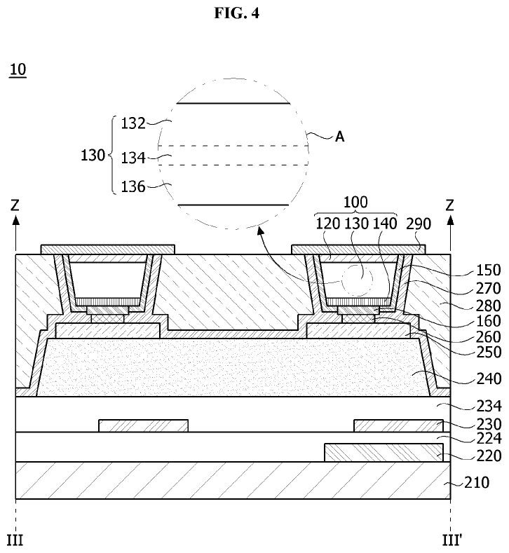

FIG. 1 is a plan view illustrating one pixel in a display panel according to one aspect of the present disclosure. FIG. 2 is a cross-sectional view illustrating a partial longitudinal cross-sectional structure of the display panel taken along line I-I′ in FIG. 1. FIG. 3 is a cross-sectional view illustrating a partial longitudinal cross-sectional structure of the display panel taken along line II-II′ in FIG. 1. FIG. 4 is a cross-sectional view illustrating a partial longitudinal cross-sectional structure of the display panel taken along line III-III′ in FIG. 1.

Referring to FIGS. 1 to 4, a display panel 10 has a length in an X-axis direction, a width in a Y-axis direction, and a thickness in a Z-axis direction. A planar shape of the display panel 10 may be a rectangular panel, or a heterogeneous panel structure including a circular shape, an oval shape, or the like. A display region or screen where an image is displayed in the display panel 10 includes a plurality of pixels PXL. Each of the pixels PXL includes a plurality of sub-pixels having different colors. For example, each of the pixels PXL may include a red sub-pixel in which a light-emitting element which emits red wavelength light is disposed, a green sub-pixel in which a light-emitting element which emits green wavelength light is disposed, and a blue sub-pixel in which a light-emitting element which emits blue wavelength light is disposed. The pixels PXL may further include white pixels.

A plurality of sub-pixels of the same color may be disposed in the pixel PXL. For example, as shown in FIG. 1, each of the pixels PXL may include a first red sub-pixel in which a 1-1 light-emitting element ED11 which emits red wavelength light is disposed, a second red sub-pixel in which a 1-2 light-emitting element ED12 which emits red wavelength light is disposed, a first green sub-pixel in which a 2-1 light-emitting element ED21 which emits green wavelength light is disposed, a second green sub-pixel in which a 2-2 light-emitting element ED22 which emits green wavelength light is disposed, a first blue sub-pixel in which a 3-1 light-emitting element ED31 which emits blue wavelength light is disposed, and a second blue sub-pixel in which a 3-2 light-emitting element ED32 which emits blue wavelength light is disposed.

When viewed from a longitudinal cross-section of the display panel 10, as shown in FIGS. 2 and 3, the display panel 10 may include a driving circuit 220 disposed on a substrate 210, a first insulating layer 224, a line pattern 230, a second insulating layer 234, a bank pattern 240, a first electrode pattern 250, a solder pattern 260, light-emitting elements ED11 to ED32, a passivation layer 150, an inorganic insulating layer 270, a diffusion layer 280, a common electrode 292, a black matrix BM, and a third insulating layer 294.

The display substrate 210 may be formed of plastic having flexibility. For example, the display substrate 210 may be fabricated as a single layer substrate or a multi-layer substrate of a material selected from polyimide, polyethylene terephthalate, polyethylene naphthalate, polycarbonate, polyethersulfone, polyarylate, polysulfone, and a cyclic-olefin copolymer, but is not limited thereto. For example, the display substrate 210 may be a glass substrate.

The driving circuit 220 which drives pixels may be disposed on the display substrate 210. The driving circuit 220 may receive a driving voltage, an image signal (a digital signal), a synchronization signal synchronized with the image signal, and the like and output an anode voltage and a cathode voltage of the light-emitting element to drive a plurality of pixels. The driving circuit 220 may receive the image signal and the synchronization signal from a host system. The host system may include a main board of a wearable system, a mobile system, a television (TV) system, a tablet computer, a notebook computer, a navigation device system, a personal computer (PC), or the like.

The driving circuit 220 may include a plurality of transistors and one or more capacitors. The transistors may include a plurality of transistors using an amorphous silicon semiconductor, a polycrystalline silicon semiconductor, or an oxide semiconductor. The transistors may be metal-oxide semiconductor field effect transistors (MOSFETs) on a semiconductor substrate. In this case, the driving circuit 220 may be integrated into a microchip, disposed on the display substrate 210, and covered by an insulating layer. One microchip may drive a plurality of pixels PXL.

When the driving circuit 220 is a microchip, after an adhesive layer (not shown in the drawings) is applied on the display substrate 210, the microchip may be transferred onto the display substrate 210 and attached to the display substrate 210 in a transfer process. The adhesive layer may be formed of an acrylic resin, a silicone resin, or the like, but is not necessarily limited thereto.

The first insulating layer 224 may be disposed on the display substrate 210 to cover the driving circuit 220. The first insulating layer 224 may be formed of an organic insulating material, for example, photosensitive acryl or photosensitive polyimide, but is not limited thereto.

A lower line pattern 230 may be disposed on the first insulating layer 224. Lines which connect the driving circuit 220 and the light-emitting elements ED11 to ED32 may be composed of lines to which line patterns separated into multiple layers are connected. In this case, an insulating layer may be disposed between line patterns disposed on different layers in the display panel 10, and the line patterns may be connected through contact holes passing through the insulating layer.

The lower line pattern 230 may be a single-layer metal line or a multi-layer metal line including aluminum (Al), titanium (Ti), copper (Cu), molybdenum (Mo), tantalum (Ta), titanium nitride (TiN), tantalum nitride (TaN), and the like. For example, the lower line pattern 230 may be a metal line stacked in a three-layer structure such as Ti/Al/Ti or Mo/Al/Mo.

The lower line pattern 230 may be covered by the second insulating layer 234. The second insulating layer 234 may be formed of an organic insulating material, for example, photosensitive acryl or photosensitive polyimide, but is not limited thereto. For example, the second insulating layer 234 may include a single layer insulating layer or a multi-layer insulating layer of an inorganic insulating material, for example, silicon oxide, silicon nitride, silicon oxynitride, and aluminum oxide, but is not limited thereto.

A plurality of bank patterns 240 may be disposed on the second insulating layer 234. Each of the bank patterns 240 may be disposed under one light-emitting element or two or more light-emitting elements. For example, as shown in FIG. 1, a first bank pattern may be disposed under the 1-1 and 1-2 light-emitting elements ED11 and ED12, and a second bank pattern may be disposed under the 2-1 and 2-2 light-emitting elements ED21 and ED22. A third bank pattern may be disposed under the 3-1 and 3-2 light-emitting elements ED31 and ED32.

The bank pattern 240 may be formed of an organic insulating material, for example, photosensitive acryl or photosensitive polyimide, but is not limited thereto. The bank pattern 240 may guide a position where the light-emitting element will be attached in the transfer process of the light-emitting element. The bank pattern 240 may be omitted.

At least one first electrode pattern 250 may be disposed on the bank pattern 240. As shown in FIG. 3, the first electrode pattern 250 may extend in one direction, for example, the X-axis direction, to cover a side surface of the bank pattern 240 and a portion of an upper surface of the second insulating layer 234.

The first electrode pattern 250 may be electrically connected to one of the lower line patterns 230 through a contact hole formed in the second insulating layer 234 and receive a signal from the driving circuit 220.

The first electrode pattern 250 may be a single metal layer or a multi-layer metal layer selected from titanium (Ti), molybdenum (Mo), aluminum (Al), and other metal materials. However, the present disclosure is not necessarily limited thereto. The first electrode pattern 250 may also be used as an anode electrode.

A transparent electrode material layer selected from indium tin oxide (ITO) and indium zinc oxide (IZO) may be stacked on this metal layer.

The solder pattern 260 may be disposed on the first electrode pattern 250. The solder pattern 260 may be formed of indium (In), tin (Sn), or an alloy thereof, but is not necessarily limited thereto. In a light-emitting region, pad patterns 160 formed on lower surfaces of first electrodes (140 in FIG. 4) of the light-emitting elements ED11 to ED32 are in contact with upper surfaces of the solder patterns 260, and the first electrode patterns 250 are in contact with lower surfaces of the solder patterns 260.

A line pattern 252 may be a single metal layer or a multi-layer metal layer selected from titanium (Ti), molybdenum (Mo), and aluminum (Al). A transparent electrode material layer selected from indium tin oxide (ITO) and indium zinc oxide (IZO) may be stacked on the metal layer.

The light-emitting elements ED11 to ED32 may be inorganic light-emitting diodes (LEDs) implementing micro-LEDs.

Further, the light-emitting elements ED11 to ED32 in the present disclosure have the same meaning as the light-emitting elements 100, and thus will be collectively described as the light-emitting elements 100 hereinafter.

The light-emitting elements 100 may be inorganic LEDs implementing micro-LEDs.

Referring to FIG. 4, the light-emitting elements 100 according to the aspect of the present disclosure may be transferred and disposed on the bank pattern 240 disposed on the display substrate 210, and overlap the bank pattern 240.

Further, the light-emitting element 100 may be in contact with the first electrode pattern 250 disposed on the bank pattern 240 and overlap the first electrode pattern 250.

The light-emitting element 100 may include a light-emitting layer 130 including a p-type first semiconductor layer 136, an n-type second semiconductor layer 132, and an active layer 134 therebetween, a first electrode 140 in contact with the p-type first semiconductor layer 136 of the light-emitting layer 130, and a second electrode 120 in contact with the n-type second semiconductor layer 132 of the light-emitting layer 130.

The first electrode 140 in contact with the p-type first semiconductor layer 136 may include an anode electrode, and the second electrode 120 in contact with the n-type second semiconductor layer 132 may include a cathode electrode. The light-emitting layer 130 may include one or more quantum well layers.

The first and second semiconductor layers 136 and 132 and the active layer 134 of the light-emitting element 100 may be made of a group II-VI or group III-V compound semiconductor. The light-emitting element 100 may be fabricated on a growth substrate through a separate fabrication process and disposed on the solder pattern 260 through a transfer process.

The light-emitting layer 130 of the light-emitting element 100 according to the aspect is a P-N junction structure in which the p-type first semiconductor layer 136, the active layer 134, and the n-type second semiconductor layer 132 are sequentially formed.

Further, the inorganic insulating layer 150 is formed on outer surfaces of the first electrode 140 and the light-emitting layer 130 of the light-emitting element 100. The inorganic insulating layer 150 may be formed of an insulating material layer including alumina (AlO₃) or an alumina series to protect the light-emitting element.

A portion of the first electrode 140 is exposed on a lower surface of the light-emitting element 100, and the pad pattern 160 is formed on the exposed first electrode 140 to form an ohmic contact.

The pad pattern 160 is bonded and electrically connected to the solder pattern 260 formed on the first electrode pattern 250 disposed on the bank pattern 240 formed on the display substrate 210, which will be described below.

An area of the pad pattern 160 is larger than or equal to an area of the solder pattern 260. Accordingly, the pad pattern 160 may be in contact with the solder pattern 260 and completely cover the solder pattern 260, or may also be in contact with the solder pattern 260 and the first electrode pattern 250 under the solder pattern 260.

Although not shown in the drawing, the pad pattern 160 may be formed in a stacked structure of a first metal layer, a second metal layer, a third metal layer, and a fourth metal layer, or in a single-layer structure formed of a single metal layer of any one of these metal layers, but is not necessarily limited thereto.

When the pad pattern 160 has a stacked structure, the second and third metal layers may be interposed between the first metal layer and the fourth metal layer. Each of the first to fourth metal layers may be formed of any one of gold (Au), aluminum (Al), and nickel (Ni), or an alloy thereof, and the first and fourth metal layers may be formed of different metals from the second and third metal layers, but are not limited thereto. The second metal layer may be formed of a different metal from the first, third, and fourth metal layers. For example, the first and fourth metal layers may contain gold (Au), the second metal layer may contain aluminum (Al), and the third metal layer may contain nickel (Ni).

The p-type first semiconductor layer 136 constituting the light-emitting layer 130 is a semiconductor layer in which holes having positive charges move as carriers to generate current, and may be formed of a p-GaN-based material. The p-GaN-based material may be GaN, AlGaN, InGaN, AlInGaN, or the like, and Mg, Zn, Be, or the like may be used as impurities used for doping the p-type first semiconductor layer.

The first electrode 140 is formed on the p-type first semiconductor layer 136 to form an ohmic contact. As the light-emitting element 100 is transferred to the panel, the light-emitting element 100 comes into contact with a pixel electrode (not shown) and may receive a voltage corresponding to a data voltage through a thin film transistor.

The n-type second semiconductor layer 132 is a semiconductor layer in which free electrons having negative charges move as carriers to generate current, and may be formed of an n-GaN-based material. The n-GaN-based material may be GaN, AlGaN, InGaN, AlInGaN, or the like, and Si, Ge, Se, Te, C, or the like may be used as impurities used for doping the n-type second semiconductor layer 132.

The active layer 134 may be disposed on the p-type first semiconductor layer 136 and may have a multi quantum well (MQW) structure having a well layer and a barrier layer having a higher band gap than the well layer. For example, the active layer 134 may have a multi-quantum well structure such as InGaN/GaN or the like.

The first electrode 140 may be in contact with the p-type first semiconductor layer 136 of the light-emitting layer 130, and the second electrode 120 may be in contact with the n-type second semiconductor layer 132.

The first electrode 140 and the second electrode 120 may be formed of a transparent electrode material or translucent electrode material, but are not necessarily limited thereto. A transparent electrode layer or translucent electrode layer may include at least one or more selected from the group including indium tin oxide (ITO), indium zinc oxide (IZO), zinc oxide (ZnO), indium oxide (In₂O₃), indium gallium oxide (IGO), and aluminum zinc oxide (AZO).

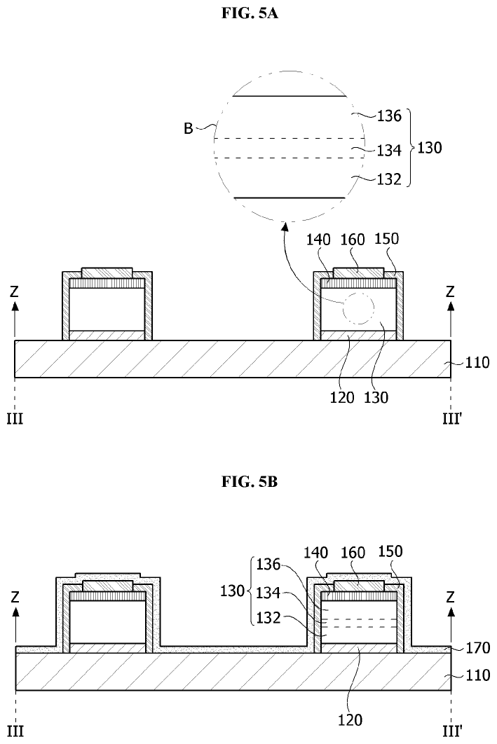

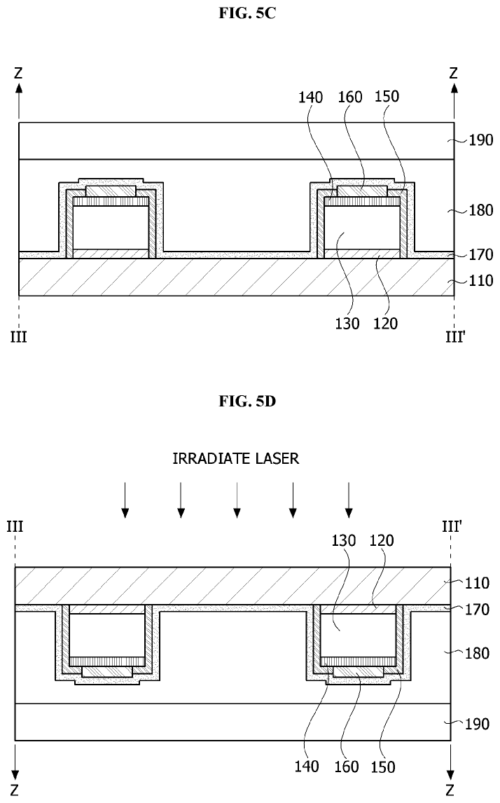

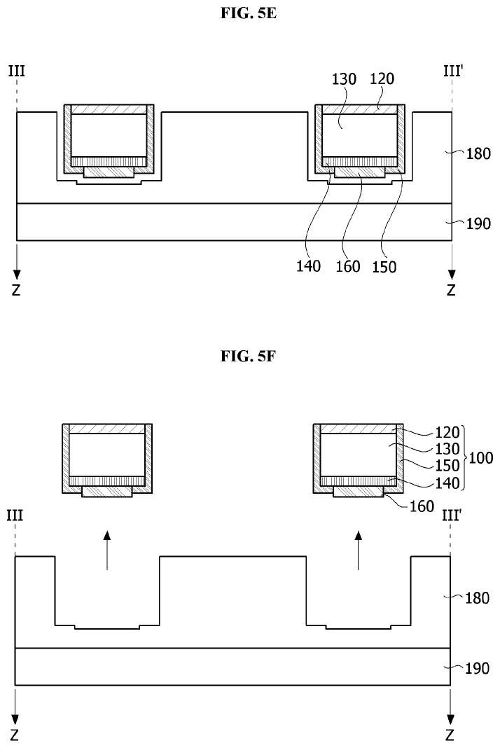

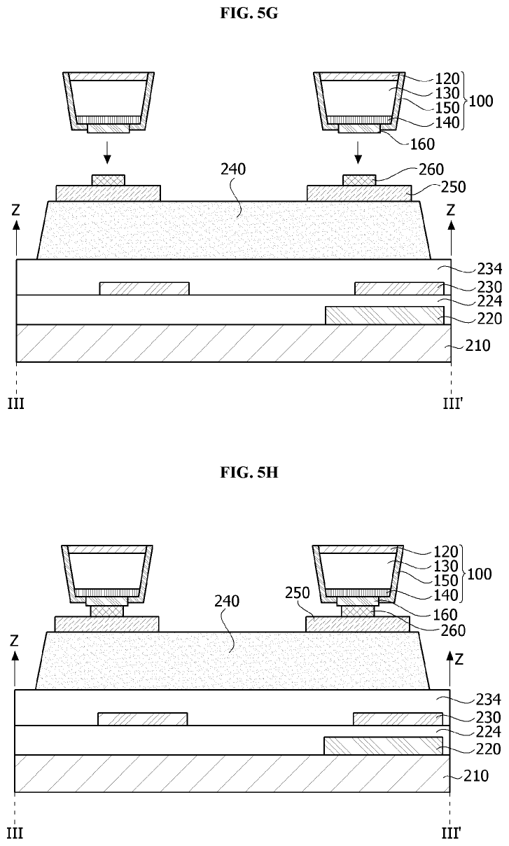

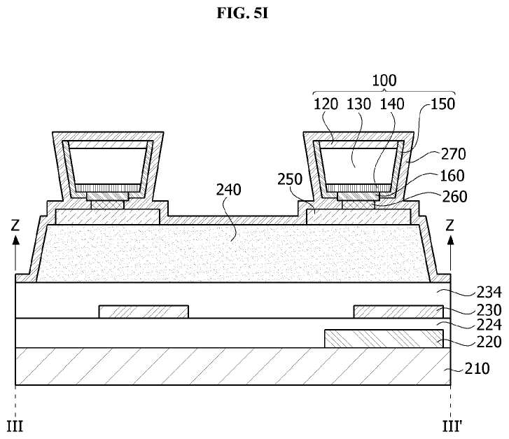

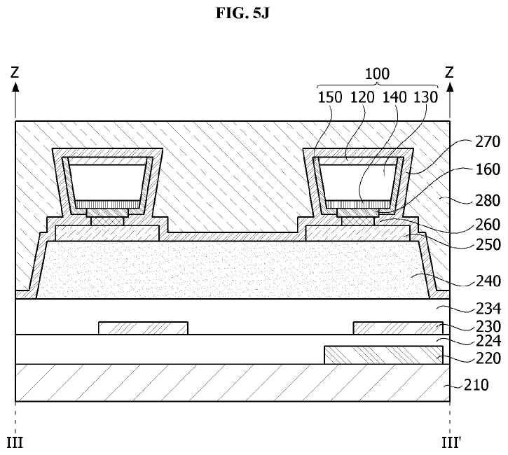

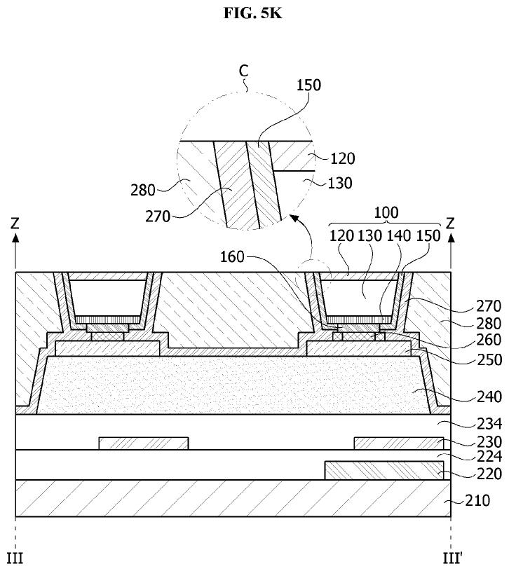

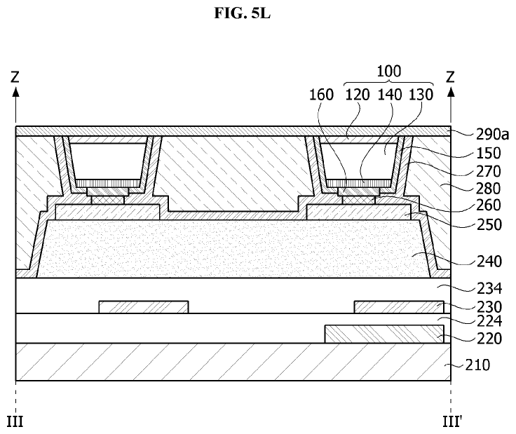

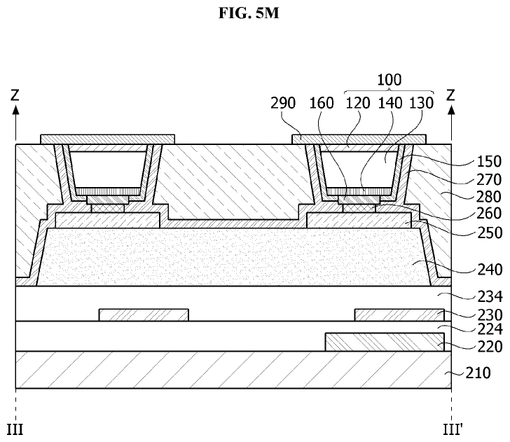

Thus, when the light-emitting element 100 formed on a growth substrate (110 in FIG. 5A) is transferred onto the display substrate 210 through a carrier substrate 190, since the first electrode 140 is connected to the pixel electrode (not shown) through the pad pattern 160, and thus a positive voltage is applied to the first electrode 140 which is in contact with the p-type first semiconductor layer 136 through the pixel electrode and a negative voltage is applied to the second electrode 120 which is in contact with the n-type second semiconductor layer 132 through the common electrode 292, current flows between the pixel electrode (not shown) and the common electrode 292 due to the movement of electrons in the n-type second semiconductor layer 132 and the flow of holes in the p-type first semiconductor layer 136.

Further, the light-emitting layer 130 emits light by recombination of electrons and holes according to the current flowing between the pixel electrode and the common electrode 292.

Referring to FIGS. 2 to 4, the display panel 10 according to the aspect of the present disclosure may include the driving circuit 220 formed on the display substrate 210, the first insulating layer 224 disposed on the driving circuit 220, the lower line patterns 230 disposed on the first insulating layer 224, the second insulating layer 234 disposed on the lower line patterns 230, the bank patterns 240 disposed on the second insulating layer 234, the first electrode patterns 250 disposed on the bank patterns 240, and the light-emitting elements 100 disposed on and adhered to the first electrode patterns 250, and connected to the first electrode patterns 250 through the solder patterns 260.

The passivation layer 150 is formed on an outer surface of the light-emitting element 100 to protect an internal element. The passivation layer 150 may include at least one selected from insulating layers containing alumina (AlOₓ), Al₂O₃, aluminum, or other metal materials. However, the present disclosure is not necessarily limited thereto.

The inorganic insulating layer 270 covers an outer surface of the passivation layer 150 and the bank pattern 240. The inorganic insulating layer 270 may cover the passivation layer 150, the pad pattern 160, the solder pattern 260, and the bank pattern 240 between the cathode electrode 290 and the second insulating layer 234.

A portion of the lower end of the inorganic insulating layer 270 may cover the upper surface of the second insulating layer 234 close to the bank pattern 240. The inorganic insulating layer 270 is formed with a thickness of 10 Å to 500 Å.

When the inorganic insulating layer 270 is formed using an inorganic material other than a silicon nitride (SiN) film, since the inorganic insulating layer 270 may not be deposited uniformly when a layer thickness is formed too thin, it is preferable that the inorganic insulating layer 270 is formed with an appropriate thickness, for example, 10 Å to 500 Å.

The inorganic insulating layer 270 may be formed by selecting at least any one from inorganic insulating materials including a silicon nitride (SiN) film and a silicon oxide (SiOₓ) film. In the aspect, an example in which a silicon nitride (SiN) film is used is described, but the present disclosure is not necessarily limited thereto. As the inorganic insulating layer 270 strengthens the adhesion between the passivation layer 150 formed of AlOₓ and the diffusion layer 280 (a sidewall diffuser, SWD), interfacial separation between the light-emitting element 100 and the diffusion layer 280 may be suppressed.

The diffusion layer 280 (the sidewall diffuser, SWD) is formed on the inorganic insulating layer 270 and the second insulating layer 234.

The diffusion layer 280 (the sidewall diffuser, SWD) may be used by selecting at least one from an organic compound in which TiOₓ is added to Si—H—O, a material containing a photo active compound (PAC) and polyimide (PI), a sidewall diffuser (SWD) from which TiOₓ is removed, and insulating materials including SiOₓ and SiN.

Since the interfacial separation between the light-emitting element 100 and the diffusion layer 280 may be suppressed by the inorganic insulating layer 270, a defect in which the cathode electrode 290 is disconnected when the cathode electrode 290 is formed on the light-emitting element 100 may be eliminated.

Since the inorganic insulating layer 270 is formed outside the light-emitting element 100, and thus the adhesion between the passivation layer 150 formed of AlOₓ on the outer surface of the light-emitting element 100 and the diffusion layer 280 is improved, missing, a rotation defect, or the like of the light-emitting element 100 which occurs during a cleaning process when the light-emitting element 100 is open is improved, and thus yield may be improved.

A second electrode pattern 290 is disposed on the light-emitting element 100, the inorganic insulating layer 270, and the diffusion layer 280 and is connected to the second electrode (120 in FIG. 4) of the light-emitting element 100. The second electrode pattern 290 may be used as a cathode electrode.

Further, a contact hole 282h is formed in the diffusion layer 280. The common electrode 292 is formed on the diffusion layer 280 including the contact hole 282h and is electrically connected to the line pattern 252 provided under the diffusion layer 280 and the second electrode pattern 290.

The line pattern 252 may be electrically connected to the lower driving circuit 220 and transmit a signal of the driving circuit 220 to the light-emitting element 100.

The black matrix BM is disposed on the common electrode 292. The black matrix BM may be formed of an organic insulating material to which black pigment is added. The common electrode 292 is in contact with the line pattern 252 under the black matrix BM.

The third insulating layer 294 is formed on the black matrix BM and the common electrode 292.

Thus, the light-emitting element 100 emits light by recombination of electrons and holes according to current flowing between the p-type first semiconductor layer 136 and the n-type second semiconductor layer 132.

The first electrode of each of the light-emitting elements 100 may be electrically connected to an anode voltage output terminal of the pixel driving circuit 220 via the solder pattern 260, the first electrode pattern 250, and at least one line pattern through the pad pattern 160 formed on a lower surface of the first electrode.

The second electrode of each of the light-emitting elements 100 may be electrically connected to a cathode voltage output terminal of the pixel driving circuit 220 via the common electrode 292, the line pattern 252, and at least one line pattern.

The passivation layers 150 are formed on the outer surfaces of the light-emitting elements 100. The passivation layer 150 may be formed of at least one of alumina (AlOₓ) and alumina-based insulating materials. However, the present disclosure is not necessarily limited thereto. The passivation layer 150 serves to protect the light-emitting element 100.

The inorganic insulating layer 270 covers the passivation layer 150 surrounding the light-emitting element 100 and the bank pattern 240. The inorganic insulating layer 270 covers the pad pattern 160, the first electrode pattern 250, and the solder pattern 260 disposed on the lower surface of the light-emitting element 100. The inorganic insulating layer 270 is also formed on the second insulating layer 234.

The inorganic insulating layer 270 serves to improve the weak adhesion between the AlOₓ passivation layer 150 and the diffusion layer 280 (SWD).

The inorganic insulating layer 270 may use at least one selected from inorganic insulating materials including a silicon nitride (SiN) film and a silicon oxide (SiOₓ) film having excellent adhesion. In the aspect, an example in which a silicon nitride (SiN) film is used is described, but the present disclosure is not necessarily limited thereto.

The inorganic insulating layer 270 may be formed with a thickness of roughly 10 Å to 500 Å to improve the adhesion between the passivation layer 150 formed of AlOₓ and the diffusion layer 280.

The diffusion layer 280 is disposed on the inorganic insulating layer 270, and is disposed between adjacent light-emitting elements 100 to planarize the light-emitting elements 100.

The diffusion layer 280 may be formed by selecting at least one from an organic compound in which TiOₓ is added to Si—H—O in which a plurality of fine metal particles are dispersed and diffused, a material containing a photo active compound (PAC) and polyimide (PI), a sidewall diffuser from which TiOₓ is removed, and insulating materials including SiOₓ and SiN.

The second electrode pattern 290 is disposed on the light-emitting element 100 and the diffusion layer 280. The second electrode pattern 290 is electrically connected to the second electrode 120 of the light-emitting element 100. The second electrode pattern 290 may be used as a cathode electrode.

The common electrode 292 may be disposed on the second electrode pattern 290 and the diffusion layer 280 and connected to all pixels PXL in common. The common electrode 292 may be a thin metal electrode which transmits light. The line pattern 252, the common electrode 292, and the black matrix BM may be stacked in a non-light-emitting region of a pixel region. The common electrode 292 may be formed of a transparent electrode material such as indium tin oxide (ITO), but is not limited thereto.

The diffusion layer 280 may include the contact hole 282h which exposes the line pattern 252. Since a portion of the common electrode 292 is formed in the contact hole 282h of the diffusion layer 280, the common electrode 292 may be in contact with an upper surface of the line pattern 252. The contact hole 282h may be formed in an outer region of the pixel in a form surrounding the bank patterns 240.

The third insulating layer 294 may be formed of an organic insulating material which covers the black matrix BM and the common electrode 292. An insulating layer (not shown) the same as the diffusion layer 280 may be evenly formed between the third insulating layer 294 and the common electrode 292. In this case, an organic insulating material layer in which fine metal molecules are dispersed may cover the common electrode 292 with a thickness thinner than that of the diffusion layer 280.

Hereinafter, a process of fabricating the display panel according to one aspect of the present disclosure will be described.

FIGS. 5A to 5M are cross-sectional views of the process of fabricating the display panel according to one aspect of the present disclosure.

Referring to FIG. 5A, a growth substrate 110 for forming an epi structure of one type of red, green, and blue forming a light-emitting element is prepared.

The growth substrate 110 may be formed of a conductive substrate or an insulating substrate. For example, the growth substrate 110 may be formed of one of sapphire, SiC, Si, GaAs, GaN, ZnO, Si, GaP, InP, Ge, and Ga₂O₃. However, the present disclosure is not limited thereto.

Next, a light-emitting element (100 in FIG. 5F) is formed by forming a p-type first semiconductor layer 136, an active layer 134, and an n-type second semiconductor layer 132 constituting a light-emitting layer 130 on the growth substrate 110, and forming a first electrode 140 and a second electrode 120 on and under the light-emitting layer 130. The p-type first semiconductor layer 136 will be described as a first semiconductor layer, and the n-type second semiconductor layer 132 will be described as a second semiconductor layer.

In this case, the first semiconductor layer 136, the active layer 134, and the second semiconductor layer 132 may be formed using a method such as an organic chemical vapor deposition (MOCVD) method, a chemical vapor deposition (CVD) method, a plasma-enhanced chemical vapor deposition (PECVD) method, a molecular beam epitaxy (MBE) method, a hydride vapor phase epitaxy (HVPE) method, or an epitaxial method.

The first semiconductor layer 136 is a semiconductor layer in which holes having positive charges move as carriers and thus current is generated.

The first semiconductor layer 136 may be selected from semiconductor materials having a composition formula of InₓAl_{y}Ga_{1-x-y}N (0≤x≤1, 0≤x−y≤1, 0≤x+y≤1), for example, GaN, AlN, AlGaN, InGaN, InN, InAlGaN, AlInN, and the like, and may be doped with a p-type dopant such as Mg, Zn, Ca, Sr, Ba, or the like.

Alternatively, the first semiconductor layer 136 may be formed of a p-GaN-based material. The p-GaN-based material may be GaN, AlGaN, InGaN, AlInGaN, or the like, and Mg, Zn, Be, or the like may be used as impurities used for doping the first semiconductor layer.

The second semiconductor layer 132 is a semiconductor layer in which free electrons having negative charges move as carriers and thus current is generated.

The second semiconductor layer 132 may be formed with, for example, a second semiconductor layer. The second semiconductor layer 132 may be selected from semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, AlInN, and the like, and may be doped with an n-type dopant such as Si, Ge, Sn, or the like.

Alternatively, the second semiconductor layer 132 may be formed of an n-GaN-based material. The n-GaN-based material may be GaN, AlGaN, InGaN, AlInGaN, or the like, and Si, Ge, Se, Te, C, or the like may be used as impurities used for doping the second semiconductor layer 132.

Further, the aspect is not limited thereto, and the first semiconductor layer 136 may include a second semiconductor layer, and the second semiconductor layer 132 may include a first semiconductor layer.

The active layer 134 is a region where electrons and holes are recombined. As the electrons and the holes are recombined, the active layer 134 may transition to a lower energy level and generate light having the corresponding wavelength.

The active layer 134 may be formed of a semiconductor material having a composition formula of, for example, InₓAl_{y}Ga_{1-x-y}N (0≤x≤1, 0≤y−x≤1, 0≤x+y≤1) and may be formed in a single quantum well structure or a multi-quantum well (MQW) structure.

Further, the active layer 134 may also include a quantum wire structure or quantum dot structure.

The active layer 134 may be disposed on the first semiconductor layer 136 and may have a multi quantum well (MQW) structure having a well layer and a barrier layer having a higher band gap than the well layer. For example, the active layer 134 may have a multi-quantum well structure such as InGaN/GaN or the like.

Subsequently, electrode material layers formed of a transparent conductive material such as indium tin oxide (ITO) or indium zinc oxide (IZO) are deposited as the first electrode 140 and the second electrode 120 formed on and under the light-emitting layer 130.

The first and second electrodes 140 and 120 may be formed of a transparent electrode material or translucent electrode material, but are not necessarily limited thereto. The transparent electrode layer or translucent electrode layer may include at least one or more selected from the group including indium tin oxide (ITO), indium zinc oxide (IZO), zinc oxide (ZnO), indium oxide (In₂O₃), indium gallium oxide (IGO), and aluminum zinc oxide (AZO).

Next, a passivation layer 150 is deposited on the growth substrate 110 including the light-emitting element 100 and then is patterned to expose a portion of the first electrode 140 of each of the light-emitting elements 100.

The passivation layer 150 is a layer formed to protect the light-emitting element 100 from the outside, and may include at least one selected from insulating layers containing alumina (AlOₓ), Al₂O₃, aluminum, or other metal materials. The present disclosure is not necessarily limited thereto.

Subsequently, a metal material layer is deposited on the entire surface of the growth substrate 110 including the exposed portion of the first electrode 140 and the passivation layer 150 and selectively patterned to form a pad pattern 160 in contact with the first electrode 140.

Although not shown in the drawings, the pad pattern 160 may be formed in a stacked structure of a first metal layer, a second metal layer, a third metal layer, and a fourth metal layer, or in a single-layer structure formed of a single metal layer of any one of these metal layers, but is not necessarily limited thereto.

When the pad pattern 160 has the stacked structure, the second and third metal layers may be interposed between the first metal layer and the fourth metal layer. Each of the first to fourth metal layers may be formed of any one of gold (Au), aluminum (Al), and nickel (Ni), or an alloy thereof, and the first and fourth metal layers may be formed of different metals from the second and third metal layers, but are not limited thereto. The second metal layer may be formed of a different metal from the first, third and fourth metal layers. For example, the first and fourth metal layers may contain gold (Au), the second metal layer may contain aluminum (Al), and the third metal layer may contain nickel (Ni).

Next, referring to FIG. 5B, a sacrificial layer 170 is formed on the entire structure of the entire growth substrate 110 including the pad pattern 160. Any one of insulating materials including a silicon oxide (SiOₓ) film, a silane-based material, and the like may be selected and used as the sacrificial layer 170.

Subsequently, referring to FIG. 5C, as a dummy insulating layer 180 is formed on the sacrificial layer 170 to planarize the growth substrate 110, the light-emitting element fabrication process on the growth substrate 110 is completed. The dummy insulating layer 180 may be formed of benzocyclobutene (BCB) or an organic insulating material, for example, photosensitive acryl or photosensitive polyimide, but is not limited thereto.

Next, referring to FIG. 5D, a carrier substrate 190 is prepared, and to transfer the light-emitting element onto the carrier substrate 190, a substrate separation process of separating the light-emitting element from the growth substrate 110 is performed.

The carrier substrate 190 may be formed of a polymer resin, glass, quartz, a synthetic resin film, a transparent substrate, or a transparent flexible polymer substrate.

Subsequently, referring to FIG. 5C, the carrier substrate 190 is disposed on and bonded to a structure including the light-emitting element formed on the growth substrate 110.

Next, referring to FIG. 5D, in a state in which the growth substrate 110 is inverted, a portion of the dummy insulating layer 180 is disposed on and bonded to the carrier substrate 190, and the growth substrate 110 is exposed to the outside.

Subsequently, laser is irradiated to a boundary portion between the growth substrate 110 and the dummy insulating layer 180, and the laser irradiated from a laser source through the growth substrate 110 may separate a light-emitting element portion from the growth substrate 110. In this case, the light-emitting element portion maintains a state of being in contact with the sacrificial layer 170 of the carrier substrate 190.

Subsequently, referring to FIGS. 5E and 5F, after the growth substrate 110 is removed through laser irradiation, the sacrificial layer 170 is removed by etching using a hydrofluoric acid-based solution so that the light-emitting element 100 is separated from the carrier substrate 190.

Methods of separating the light-emitting element 100 from the carrier substrate 190 may include laser lift-off (LLO), chemical lift off (CLO), applying pressure using a stamp, and the like. However, the present disclosure is not necessarily limited thereto.

Through performing this substrate separation process, the light-emitting element 100 may be separated from the carrier substrate 190.

Next, referring to FIG. 5G, to transfer the separated light-emitting element 100 onto a display substrate 210, the display substrate 210 on which a driving circuit 220 is formed is prepared.

Subsequently, the driving circuit 220 is formed on the display substrate 210, and a first insulating layer 224 is formed on the display substrate 210 including the driving circuit 220.

The display substrate 210 may be formed of plastic having flexibility. For example, the display substrate 210 may be fabricated as a single layer or a multi-layer substrate of a material selected from polyimide, polyethylene terephthalate, polyethylene naphthalate, polycarbonate, polyethersulfone, and polyarylate, polysulfone, and a cyclic-olefin copolymer, but is not limited thereto. For example, the display substrate 210 may be a glass substrate.

The first insulating layer 224 may be formed of an organic insulating material, for example, photosensitive acryl or photosensitive polyimide, but is not limited thereto.

Next, a lower line pattern 230 is formed on the first insulating layer 224, and a second insulating layer 234 is formed on the lower line pattern 230.

Lines which connect the driving circuit 220 and the light-emitting elements may be composed of lines to which line patterns separated into multiple layers are connected.

In this case, an insulating layer may be disposed between line patterns disposed on different layers in the display panel, and the line patterns may be connected through contact holes passing through the insulating layer.

The lower line pattern 230 may be a single-layer metal line or multi-layer metal line including aluminum (Al), titanium (Ti), copper (Cu), molybdenum (Mo), tantalum (Ta), titanium nitride (TiN), tantalum nitride (TaN), and the like. For example, the lower line pattern 230 may be a metal line stacked in a three-layer structure such as Ti/Al/Ti or Mo/Al/Mo.

The second insulating layer 234 may be formed of an organic insulating material, for example, photosensitive acryl or photosensitive polyimide, but is not limited thereto. For example, the second insulating layer 234 may include a single layer insulating layer or a multi-layer insulating layer of an inorganic insulating material, for example, silicon oxide, silicon nitride, silicon oxynitride, and aluminum oxide, but is not limited thereto.

Subsequently, a bank pattern 240 may be formed on the second insulating layer 234, and a first electrode pattern 250 and the line pattern (252 in FIG. 2) may be formed on the bank pattern 240 and the second insulating layer 234.

Each of the bank patterns 240 may be disposed under one light-emitting element 100 or two or more light-emitting elements.

The bank pattern 240 may be formed of an organic insulating material, for example, photosensitive acryl or photosensitive polyimide, but is not limited thereto. The bank pattern 240 may guide a position where the light-emitting element will be attached in the transfer process of the light-emitting element. The bank pattern 240 may be omitted.

At least one first electrode pattern 250 may be disposed on the bank pattern 240.

The first electrode pattern 250 may be a single metal layer or a multi-layer metal layer selected from titanium (Ti), molybdenum (Mo), and aluminum (Al). However, the present disclosure is not necessarily limited thereto.

A transparent electrode material layer selected from indium tin oxide (ITO) and indium zinc oxide (IZO) may be stacked on this metal layer.

Further, the line pattern 252 is formed on the second insulating layer 234 in a region except for the bank pattern 240. In this case, the line pattern 252 may be formed simultaneously using the same material as the above-described first electrode pattern 250.

Subsequently, a solder pattern 260 may be disposed on the first electrode pattern 250. The solder pattern 260 may be formed of indium (In), tin (Sn), or an alloy thereof, but is not limited thereto. In the light-emitting region, the pad pattern 160 formed on the lower surface of the first electrode 140 of the light-emitting element 100 may be in contact with the upper surface of the solder pattern 260, and the first electrode pattern 250 may be in contact with the lower surface of the solder pattern 260.

Next, referring to FIG. 5H, the light-emitting element 100 separated from the carrier substrate 190 is disposed on and bonded to the display substrate 210.

The pad pattern 160 formed on the lower surface of the light-emitting element 100 is disposed in contact with the solder pattern 260 disposed on the bank pattern 240 on the display substrate 210. The pad pattern 160 may be disposed in contact with not only the solder pattern 260 but also the first electrode pattern 250. However, the present disclosure is not necessarily limited thereto.

The pad pattern 160 may have the same area as or a larger area than the solder pattern 260. When the area of the pad pattern 160 is larger than the area of the solder pattern 260, the pad pattern 160 is in contact with the solder pattern 260 and the first electrode pattern 250 under the solder pattern 260, and thus may be more stably disposed on and bonded to the solder pattern 260.

In the light-emitting element 100, the pad pattern 160 is disposed in contact with the solder pattern 260 and bonded to the solder pattern 260, and a separate adhesive layer (not shown) may be used as a bonding means, but is not limited thereto.

The first electrode 140 of each of the light-emitting elements 100 may be electrically connected to an anode voltage output terminal of the driving circuit 220 through the pad pattern 160 formed on the lower surface thereof via the solder pattern 260, the first electrode pattern 250, and at least one line pattern.

The second electrode 120 of each of the light-emitting elements 100 may be electrically connected to a cathode voltage output terminal of the driving circuit 220 via the common electrode 292, the line pattern 252, and at least one line pattern.

Next, referring to FIG. 5I, the passivation layer 150 surrounding the light-emitting element 100 and an inorganic insulating layer 270 which covers the bank pattern 240 are disposed. The inorganic insulating layer 270 covers the pad pattern 160, the first electrode pattern 250, and the solder pattern 260 disposed on the lower surface of the light-emitting element 100. The inorganic insulating layer 270 is also formed on the second insulating layer 234.

The inorganic insulating layer 270 may use at least one selected from inorganic insulating materials including a silicon nitride (SiN) film and a silicon oxide (SiO₂) film having excellent adhesion. In the aspect, an example in which a silicon nitride (SiN) film having more excellent adhesion than a silicon oxide film is used is described, but the present disclosure is not limited thereto.

The inorganic insulating layer 270 may be formed with a thickness of roughly 10 Å to 500 Å to have excellent adhesion. However, the present disclosure is not necessarily limited thereto, and any insulating material capable of improving the adhesion between the passivation layer 150 formed of AlOₓ and the diffusion layer (or the side wall diffuser SWD) to be described below may be used.

When the inorganic insulating layer 270 is formed using an inorganic material other than silicon nitride (SiN), since the inorganic insulating layer 270 may not be deposited uniformly when a layer thickness is formed too thin, it is preferable that the inorganic insulating layer 270 is formed with an appropriate thickness, for example, 10 Å to 500 Å.

An atomic layer deposition (ALD) method in which fine adjustment of the film thickness is possible may be used as a deposition method of the inorganic insulating layer 270. The ALD method is more preferable for forming a thin layer than a method in which fine adjustment of the film thickness is difficult such as a chemical vapor deposition (CVD) method which is a chemical method or a physical vapor deposition (PVD) method which is a physical method. However, the present disclosure is not necessarily limited thereto.

Next, referring to FIG. 5J, a diffusion layer 280 is disposed on the inorganic insulating layer 270, and disposed between adjacent light-emitting elements 100 to planarize the light-emitting elements 100.

The diffusion layer 280 may be formed from an organic compound in which TiOₓ is added to Si—H—O in which a plurality of fine metal particles are dispersed and diffused, a material containing a photo active compound (PAC) and polyimide (PI), a sidewall diffuser from which TiOₓ is removed, and insulating materials including SiOₓ and SiN.

Since the inorganic insulating layer 270 strengthens the adhesion between the passivation layer 150 formed of AlOₓ on an outer surface of the light-emitting element 100 and the diffusion layer 280 (or the side wall diffuser SWD), and thus the adhesion between the light-emitting element 100 and the diffusion layer 280 is improved and interfacial separation is suppressed, a disconnection defect of a cathode electrode 290 disposed on the light-emitting element 100 may be eliminated.

Then, before forming the diffusion layer 280 on the light-emitting element 100 after the light-emitting element 100 is transferred, as the inorganic insulating layer 270 formed of a silicon nitride (SiN) film among the inorganic insulating materials is formed on the light-emitting element 100, and thus the adhesion between the passivation layer 150 and the diffusion layer 280 on the outer surface of the light-emitting element 100 is strengthened, missing, a rotation defect, or the like of the light-emitting element 100 which occurs during a cleaning process when the light-emitting element 100 is open is improved, and thus yield may be improved.

Next, referring to FIG. 5K, the diffusion layer 280 and the inorganic insulating layer 270 are planarized to expose the second electrode 120 of the light-emitting element 100.

As shown in C in FIG. 5K, since the inorganic insulating layer 270 strengthens the adhesion between the passivation layer 150 formed of AlOₓ on the outer surface of the light-emitting element 100 and the diffusion layer 280, there is no occurrence of interfacial separation by the expansion or contraction of the diffusion layer 280 due to the generation of a gap by the weakened adhesion between the passivation layer 150 formed of AlOₓ on the light-emitting element and the diffusion layer 280 as in the past.

Subsequently, referring to FIG. 5L, a metal conductive layer 290a is formed on the diffusion layer 280 including the exposed second electrode 120.

The metal conductive layer 290a may be formed of a transparent electrode material or translucent electrode material, but is not necessarily limited thereto. The transparent electrode layer or translucent electrode layer may include one of indium tin oxide (ITO), indium zinc oxide (IZO), zinc oxide (ZnO), indium oxide (In₂O₃), indium gallium oxide (IGO), and aluminum zinc oxide (AZO).

Next, referring to FIG. 5M, the metal conductive layer 290a is selectively patterned through a mask process using a photolithography process to form a second electrode pattern 290 connected to the second electrode 120 of the light-emitting element 100. The second electrode pattern 290 may be used as a cathode electrode.

Subsequently, although not shown in the drawings, the diffusion layer 280 is selectively etched through a mask process using a photolithography process to form contact holes (282h in FIG. 2) which expose the line pattern 252 of the light-emitting element 100.

Subsequently, a common electrode 292 which connects the first electrode pattern 250 and the cathode electrode 290 through the contact hole 282h is formed on the diffusion layer 280.

The common electrode 292 may be disposed on the diffusion layer 280 and connected to all pixels PXL in common. The common electrode 292 may be a thin metal electrode which transmits light. The line pattern 252, the common electrode 292, and a black matrix BM may be stacked in the non-light-emitting region of the pixel region. The common electrode 292 may be a transparent electrode material such as indium tin oxide (ITO), but is not limited thereto.

Next, although not shown in the drawings, the black matrix BM is formed in a region of the common electrode 292 on the line pattern 252. The black matrix BM may be formed of an organic insulating material to which black pigment is added

Subsequently, although not shown in the drawings, a third insulating layer 294 is formed on the black matrix BM and the common electrode 292. The third insulating layer 294 may be an organic insulating material which covers the black matrix BM and the common electrode 292. An insulating layer the same as the diffusion layer 280 may be evenly formed between the third insulating layer 294 and the common electrode 292. In this case, an organic insulating material layer in which fine metal molecules are dispersed may cover the common electrode 292 with a thickness thinner than that of the diffusion layer 280.

As described above, when the light-emitting element 100 is transferred onto the display substrate 210, since the first electrode 140 is connected to the pixel electrode (not shown) through the pad pattern 160, and thus a positive voltage is applied to the first electrode 140 through the pixel electrode and a negative voltage is applied to the second electrode 120 through the common electrode 292, current flows between the pixel electrode (not shown) and the common electrode 292 due to the movement of electrons in the n-type second semiconductor layer and the flow of holes in the p-type first semiconductor layer.

In the present disclosure, even when contraction or expansion of a diffusion layer (a sidewall diffuser, SWD) occurs, the occurrence of interfacial separation between a light-emitting element and the diffusion layer (SWD) may be eliminated due to the strong adhesion of an inorganic insulating layer formed on an outer surface of the light-emitting element.

Since an inorganic insulating layer is formed on a light-emitting element and may improve the adhesion between a passivation layer on an outer surface of the light-emitting element and a diffusion layer (the sidewall diffuser, SWD), a cathode disconnection defect due to the interfacial separation between the light-emitting element and the diffusion layer may be improved.

Further, in the present disclosure, since the adhesion between a light-emitting element and a solder pattern of a display substrate during transferring of the light-emitting element may be improved by forming an inorganic insulating layer on an outer surface of the light-emitting element and strengthening the adhesion between the light-emitting element and a display panel, missing, a rotation defect, or the like of the light-emitting element which occurs during a cleaning process may be improved, and thus yield may be improved.

A display panel and a method of fabricating of fabricating the display panel according to one or more embodiments of the present disclosure may be described as follows.

A display panel according to one or more embodiments of the present disclosure may include a bank pattern disposed on a substrate, a first electrode pattern disposed on the bank pattern, a light-emitting element disposed on the first electrode pattern to be electrically connected to the first electrode pattern, a second electrode pattern configured to cover the light-emitting element, an inorganic insulating layer configured to cover the bank pattern, the first electrode pattern, and the light-emitting element between the first electrode pattern and the second electrode pattern, and a diffusion layer which includes a plurality of diffusion particles and is in contact with the inorganic insulating layer.

The inorganic insulating layer may be at least one selected from inorganic insulating materials including a silicon nitride (SiN) film and a silicon oxide (SiO₂) film.

The inorganic insulating layer may be formed with a thickness of 10 Å to 500 Å.

The diffusion layer may be formed by selecting at least one from an organic compound in which TiOₓ is added to Si—H—O, a material containing a photo active compound (PAC) and polyimide (PI), a sidewall diffuser (SWD) from which TiOₓ is removed, and an insulating material containing SiOₓ and SiN.

The light-emitting element may include a p-type first semiconductor layer, an n-type second semiconductor layer, and an active layer interposed between the p-type first semiconductor layer and the n-type second semiconductor layer.

The light-emitting element may further include a first electrode in contact with the p-type first semiconductor layer and a second electrode in contact with the n-type second semiconductor layer.

A pad pattern connected to the first electrode pattern may be disposed on a lower surface of the light-emitting element.

A solder pattern in contact with the pad pattern may be disposed on the first electrode pattern.

The pad pattern may have an area the same as or larger than an area of the solder pattern.

The display panel may further include a passivation layer disposed on an outer surface of the light-emitting element, and in contact with the inorganic insulating layer.

The passivation layer may be formed of at least one selected from insulating materials including alumina (AlOₓ), Al₂O₃, and aluminum.

The first electrode pattern may include an anode electrode, and the second electrode pattern may include a cathode electrode.

A driving circuit and an insulating layer may be disposed between the bank pattern, the inorganic insulating layer, and the diffusion layer, and the substrate.

A method of fabricating a display panel according to one or more embodiments of the present disclosure may include forming a bank pattern on a substrate, forming a first electrode pattern on the bank pattern, disposing a light-emitting element on the first electrode pattern to be electrically connected to the first electrode pattern, disposing an inorganic insulating layer configured to cover the bank pattern, the first electrode pattern, and the light-emitting element, disposing a diffusion layer which includes plurality of diffusion particles and is in contact with the inorganic insulating layer, planarizing the diffusion layer and the inorganic insulating layer to expose an upper portion of the light-emitting element, and disposing a second electrode pattern configured to cover the light-emitting element, the inorganic insulating layer, and the diffusion layer.

The inorganic insulating layer may be at least one selected from inorganic insulating materials including a silicon nitride (SiN) film and a silicon oxide (SiO₂) film.

The inorganic insulating layer may be formed with a thickness of 10 Å to 500 Å.

The diffusion layer may be formed by selecting at least one from an organic compound in which TiOₓ is added to Si—H—O, a material containing a photo active compound (PAC) and polyimide (PI), a sidewall diffuser (SWD) from which TiOₓ is removed, and an insulating material containing SiOₓ and SiN.

The method may further include disposing a pad pattern connected to the first electrode pattern on a lower surface of the light-emitting element.

The method may further include disposing a solder pattern in contact with the pad pattern on the first electrode pattern.

The method may further include disposing a passivation layer in contact with the inorganic insulating layer on an outer surface of the light-emitting element.

The passivation layer may be formed of at least one selected from insulating materials including alumina (AlOₓ), Al₂O₃, and aluminum.

The first electrode pattern may include an anode electrode, and the second electrode pattern may include a cathode electrode.

The method may further include disposing a driving circuit and an insulating layer between the bank pattern, the inorganic insulating layer, and the diffusion layer, and the substrate.

The effects of the present disclosure are not limited to the effects mentioned above, and other effects not mentioned may be clearly understood by those skilled in the art from the description of the claims.

While the embodiments have been described in detail above with reference to the accompanying drawings, the present disclosure is not necessarily limited to these embodiments, and various changes and modifications may be made without departing from the technical spirit of the present disclosure. Accordingly, the embodiments disclosed herein are to be considered descriptive and not restrictive of the technical spirit of the present disclosure, and the scope of the technical spirit of the present disclosure is not limited by these embodiments. Therefore, the above-described embodiments should be understood to be exemplary and not limiting in any aspect.

What is claimed is:

1. A display panel comprising:
a bank pattern disposed on a substrate;
a first electrode pattern disposed on the bank pattern;
a light-emitting element disposed on the first electrode pattern and electrically connected to the first electrode pattern;
a second electrode pattern configured to cover the light-emitting element;
an inorganic insulating layer configured to cover the bank pattern, the first electrode pattern, and the light-emitting element between the first electrode pattern and the second electrode pattern; and
a diffusion layer which includes a plurality of diffusion particles and is in contact with the inorganic insulating layer.

2. The display panel of claim 1, wherein the inorganic insulating layer includes a silicon nitride (SiN) film and a silicon oxide (SiO₂) film.

3. The display panel of claim 1, wherein the inorganic insulating layer has a thickness of 10 Å to 500 Å.

4. The display panel of claim 1, wherein the diffusion layer is formed of an organic compound in which TiOₓ is added to Si—H—O, a material containing a photo active compound (PAC) and polyimide (PI), a sidewall diffuser (SWD) from which TiOₓ is removed, and an insulating material containing SiOₓ and SiN.

5. The display panel of claim 1, wherein the light-emitting element includes a p-type first semiconductor layer, an n-type second semiconductor layer, and an active layer interposed between the p-type first semiconductor layer and the n-type second semiconductor layer.

6. The display panel of claim 5, wherein the light-emitting element further includes a first electrode in contact with the p-type first semiconductor layer and a second electrode in contact with the n-type second semiconductor layer.

7. The display panel of claim 1, further comprising a pad pattern connected to the first electrode pattern disposed on a lower surface of the light-emitting element.

8. The display panel of claim 1, further comprising a solder pattern in contact with the pad pattern disposed on the first electrode pattern.

9. The display panel of claim 8, wherein the pad pattern has a same area as or larger than an area of the solder pattern.

10. The display panel of claim 1, further comprising a passivation layer disposed on an outer surface of the light-emitting element, and in contact with the inorganic insulating layer.

11. The display panel of claim 10, wherein the passivation layer is formed of insulating materials including alumina (AlOₓ), Al₂O₃, and aluminum.

12. The display panel of claim 1, wherein the first electrode pattern includes an anode electrode; and
wherein the second electrode pattern includes a cathode electrode.

13. The display panel of claim 1, wherein a driving circuit and an insulating layer are disposed between the bank pattern, the inorganic insulating layer, and the diffusion layer, and the substrate.

14. A method of fabricating a display panel, comprising:
forming a bank pattern on a substrate;
forming a first electrode pattern on the bank pattern;
disposing a light-emitting element on the first electrode pattern to be electrically connected to the first electrode pattern;
disposing an inorganic insulating layer configured to cover the bank pattern, the first electrode pattern, and the light-emitting element;
disposing a diffusion layer which includes plurality of diffusion particles and is in contact with the inorganic insulating layer;
planarizing the diffusion layer and the inorganic insulating layer to expose an upper portion of the light-emitting element; and
disposing a second electrode pattern configured to cover the light-emitting element, the inorganic insulating layer, and the diffusion layer.

15. The method of claim 14, wherein the inorganic insulating layer includes a silicon nitride (SiN) film and a silicon oxide (SiO₂) film.

16. The method of claim 14, wherein the inorganic insulating layer is formed with a thickness of 10 Å to 500 Å.

17. The method of claim 14, wherein the diffusion layer is formed by selecting at least one from an organic compound in which TiOₓ is added to Si—H—O, a material containing a photo active compound (PAC) and polyimide (PI), a sidewall diffuser (SWD) from which TiOₓ is removed, and an insulating material containing SiOₓ and SiN.

18. The method of claim 14, further comprising disposing a pad pattern connected to the first electrode pattern on a lower surface of the light-emitting element.

19. The method of claim 14, further comprising disposing a solder pattern in contact with the pad pattern on the first electrode pattern.

20. The method of claim 14, further comprising disposing a passivation layer in contact with the inorganic insulating layer on an outer surface of the light-emitting element.

21. The method of claim 20, wherein the passivation layer is formed of an insulating material including alumina (AlOₓ), Al₂O₃, and aluminum.

22. The method of claim 14, wherein the first electrode pattern includes an anode electrode; and
wherein the second electrode pattern includes a cathode electrode.

23. The method of claim 14, further comprising disposing a driving circuit and an insulating layer between the bank pattern, the inorganic insulating layer, and the diffusion layer, and the substrate.
